(19) United States
(12) Patent Application Publication
(10) Pub. No.: US 2026/0068481 A1
(43) Pub. Date: Mar. 5, 2026

(54) DISPLAY PANEL AND DRIVING METHOD THEREOF, AND DISPLAY APPARATUS

(71) Applicant: HKC CORPORATION LIMITED, Baoan District (CN)

(72) Inventors: Liao XU, Shenzhen (CN); Lidan YE, Shenzhen (CN)

(21) Appl. No.: 19/312,763

(22) Filed: Aug. 28, 2025

(30) Foreign Application Priority Data
Sep. 3, 2024 (CN) 202411225664.8

(51) Int. Cl. H10K 59/80; G09G 3/00; G09G 3/3225; H10K 59/35

(52) U.S. Cl. CPC H10K 59/80522; G09G 3/006; G09G 3/3225; H10K 59/353; G09G 2300/043

(57) ABSTRACT

A display panel and a driving method thereof, and a display apparatus are provided. The display panel includes a cathode layer, a blue sub-pixel, and a compensation cathode. The blue sub-pixel is stacked on the cathode layer, and the compensation cathode is disposed on one side of the cathode layer facing away from the blue sub-pixel. The compensation cathode and the blue sub-pixel are disposed opposite to each other in a first direction, and the first direction is a stacking direction of the blue sub-pixel and the cathode layer.

### CROSS-REFERENCE TO RELATED APPLICATIONS

This application claims priority under 35 U.S. C. § 119(a) to Chinese Patent Application No. 202411225664.8, filed Sep. 3, 2024, the entire disclosure of which is incorporated herein by reference.

### TECHNICAL FIELD

The present disclosure relates to the field of light-emitting diode technology, and in particular, to a display panel and a driving method thereof, and a display apparatus.

### BACKGROUND

Organic Light-Emitting Diode (OLED) display, as a commonly used display technology, is widely applied. Since the light-emitting efficiency of blue sub-pixels is relatively low and the light-emitting lifetime of blue sub-pixels is relatively short, larger blue pixels are generally required in design. Consequently, a combined Red-Green-Blue (RGB) pixel occupies a relatively large area, resulting in low pixels per inch (PPI) of a display panel.

### SUMMARY

In a first aspect, the disclosure provides a display panel, including a cathode layer, a blue sub-pixel stacked on the cathode layer, and a compensation cathode disposed on one side of the cathode layer facing away from the blue sub-pixel. The compensation cathode and the blue sub-pixel are disposed opposite to each other in a first direction, and the first direction is a stacking direction of the blue sub-pixel and the cathode layer.

In a second aspect, the disclosure provides a display apparatus. The display apparatus includes a housing and the display panel of any embodiments of the first aspect. The display panel is accommodated in the housing.

In a third aspect, the disclosure provides a driving method of a display panel, and the method is used for driving the display panel of any embodiments of the first aspect. The method includes the following. A first voltage is provided to the cathode layer. A second voltage is provided to the compensation cathode.

### BRIEF DESCRIPTION OF THE DRAWINGS

In order to describe technical solutions of embodiments of the disclosure more clearly, the following will give a brief introduction to the accompanying drawings used for describing the embodiments. Apparently, the accompanying drawings hereinafter described are some embodiments of the present disclosure. Based on these drawings, those of ordinary skill in the art can also obtain other drawings without creative effort.

FIG. 1 is a side view of a display panel of an embodiment.

FIG. 2 is a front view of a display panel of an embodiment.

FIG. 3 is a schematic view of a display apparatus of an embodiment.

FIG. 4 is a flow chart of a driving method of a display panel of an embodiment.

FIG. 5 is a schematic view of a first voltage and a second voltage of an embodiment.

FIG. 6 is a flow chart of another step in a driving method of a display panel of an embodiment.

### DESCRIPTION OF REFERENCE SIGNS

100-display panel, 10-cathode layer, 20-compensation cathode, 30-pixel, 31-blue sub-pixel, 32-green sub-pixel, 33-red sub-pixel, 40-anode layer, 41-blue-pixel region anode, 42-green-pixel region anode, 43-red-pixel region anode, 200-housing, X-first direction, Y-second direction, Z-third direction, V1-first voltage, V2-second voltage.

### DETAILED DESCRIPTION

The following will clearly and completely illustrate technical solutions of embodiments of the disclosure with reference to the accompanying drawings of embodiments of the disclosure. Apparently, embodiments described herein are merely some embodiments, rather than all embodiments, of the disclosure. Based on the embodiments of the disclosure, all other embodiments obtained by those of ordinary skill in the art without creative effort shall fall within the protection scope of the disclosure.

It is to be noted that, when one component is referred to as “fixed to” another component, it may be directly on the another component or it is also possible that there is a third component between them. When one component is considered to “connect” another component, it may be directly connected to the another component or it is possible that there is a third component between them.

Unless otherwise defined, all the technical and scientific terms used in the present disclosure have the same or similar meanings as generally understood by those of ordinary skill in the art. As described in the present disclosure, the terms used in the specification of the present disclosure are intended to describe specific embodiments, instead of limiting the present disclosure. The term “and/or” as used herein includes any and all combinations of one or more related listed items.

Some embodiments will be described in the following with reference to the accompanying drawings. In the case where there is no conflict between the embodiments, the features of the following embodiments and the embodiments may be combined with each other.

Since the light-emitting efficiency of blue sub-pixels is relatively low and the light-emitting lifetime of blue sub-pixels is relatively short, larger blue pixels are generally required in design. Consequently, a combined Red-Green-Blue (RGB) pixel occupies a relatively large area, resulting in low pixels per inch (PPI) of a display panel.

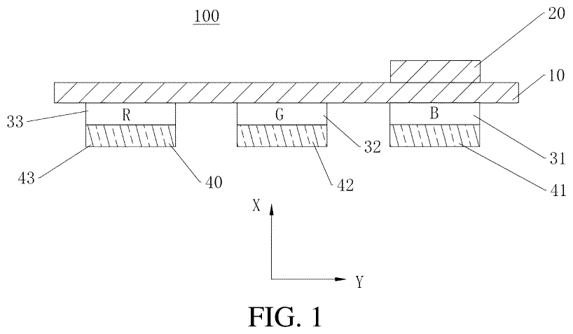

Reference is made to FIG. 1, the disclosure provides a display panel 100 including a cathode layer 10, a blue sub-pixel 31, and a compensation cathode 20. The blue sub-pixel 31 is stacked on the cathode layer 10. The compensation cathode 20 is disposed on one side of the cathode layer 10 facing away from the blue sub-pixel 31. The compensation cathode 20 and the blue sub-pixel 31 are disposed opposite to each other in a first direction X, and the first direction X is a stacking direction of the blue sub-pixel 31 and the cathode layer 10.

The compensation cathode 20 is made of the same material as the cathode layer 10. The cathode layer 10 may be a single-layer metal cathode, an alloy cathode, etc., which is not limited herein. Optionally, the single-layer metal may be made of Ag, Al, Li, Mg, Ca, In, etc., and the alloy cathode may be made of Mg:Ag, Li:Al, etc., which is not limited herein. Specifically, when the display panel 100 is a bottom-emitting display panel, the materials of the cathode layer 10 and the compensation cathode 20 are Al. When the display panel 100 is a top-emitting display panel, the materials of the cathode layer 10 and the compensation cathode 20 are Mg:Ag, and a mass ratio of Mg:Ag may be 1:9.

The material of the blue sub-pixel 31 may be fluorescent material, phosphorescent material, etc., which is not limited herein. The blue sub-pixel 31 may be circular, oval, rectangular, etc., which is not limited herein.

In the display panel 100 of the disclosure, the blue sub-pixel 31 is disposed on the cathode layer 10 and the compensation cathode 20 is correspondingly disposed on one side of the cathode layer 10 facing away from the blue sub-pixel 31, thereby increasing the total cathode thickness corresponding to the blue sub-pixel 31. According to a resistance formula R=ρl/s, the cross-sectional area of the compensation cathode increases, thus reducing the resistance in the region corresponding to the blue sub-pixel 31. When a PVEE signal is input, the electric field distribution weakens from the position of the compensation cathode 20 corresponding to the blue sub-pixel 31 to other regions. Therefore, the electric field strength at the position of the compensation cathode corresponding to the blue sub-pixel 31 is relatively high, thereby enhancing the driving voltage difference of the blue sub-pixel 31. In addition, the PVEE signal corresponding to the blue sub-pixel 31 becomes more stable, thereby ensuring the light-emitting current of the blue sub-pixel 31. Therefore, the area of the blue sub-pixel 31 may be reduced, allowing more pixels 30 to be accommodated in the display panel 100 within the same area, achieving the increase of PPI, i.e., the display panel 100 exhibits high PPI. Consequently, the image definition and resolution of the display panel 100 may be improved.

Optionally, the disclosure provides a manufacturing method for a display panel 100, and the method includes the following. A cathode layer 10 is provided. A blue sub-pixel 31 is formed on the cathode layer 10. A compensation cathode 20 is formed on one surface of the cathode layer 10 facing away from the blue sub-pixel 31, with the compensation cathode 20 disposed corresponding to the blue sub-pixel 31. Optionally, the method for forming the blue sub-pixel 31 on the cathode layer 10 and the method for forming the compensation cathode 20 on one surface of the cathode layer 10 facing away from the blue sub-pixel 31 may be evaporation, printing, etc., which is not limited herein.

Reference is made to FIG. 1, in an embodiment, an orthographic projection of the compensation cathode 20 in the first direction X is located within the blue sub-pixel 31.

The orthographic projection of the compensation cathode 20 in the first direction X may be the same as the orthographic projection of the blue sub-pixel 31 in the first direction X. The orthographic projection of the compensation cathode 20 in the first direction X may be smaller than the orthographic projection of the blue sub-pixel 31 in the first direction X and located within the orthographic projection of the blue sub-pixel 31 in the first direction X.

The orthographic projection of the compensation cathode 20 in the first direction X may be disposed at the center of the blue sub-pixel 31 or at an edge region of the blue sub-pixel 31, which is not limited herein.

Since the electric field distribution weakens from the position of the compensation cathode 20 corresponding to the blue sub-pixel 31 to other regions when a PVEE signal is input, the electric field strength at the position of the compensation cathode 20 corresponding to the blue sub-pixel 31 is relatively high. Therefore, the compensation cathode 20 does not need to be completely aligned with the blue sub-pixel 31, which helps reduce the production cost of the display panel 100 and lower the weight of the display panel 100.

In an embodiment, a dimension of the cathode layer 10 in the first direction X is d1, a dimension of the compensation cathode 20 in the first direction X is d2, and d1 and d2 satisfy: 0.1d1≤d2≤0.5d1.

When d2>0.5d1, the resistance corresponding to the compensation cathode 20 and the cathode layer 10 decrease, but the light output rate of the display panel 100 is reduced, affecting display effect. When d2<0.1d1, the resistance corresponding to the compensation cathode 20 and the cathode layer 10 increase, causing severe voltage drop and affecting light-emitting uniformity and device efficiency. When 0.1d1≤d2≤0.5d1, the compensation cathode 20 can both reduce the resistance in the region corresponding to the blue sub-pixel 31 and maintain the light transmittance in the region corresponding to the blue sub-pixel 31, thereby ensuring optimal light output rate and light-emitting uniformity of the display panel 100.

Optionally, d2 may be 0.1d1, 0.2d1, 0.3d1, 0.4d1, 0.5d1, etc., which is not limited herein. When the display panel 100 is a bottom-emitting display panel, the compensation cathode 20 may be disposed without considering the light transmittance. Therefore, the dimension of the compensation cathode 20 in the first direction X may be 0.5d1. Specifically, when the thickness of the cathode layer 10 is 2500 Ångström (Å), the corresponding thickness of the compensation cathode 20 is 1250 Å. When the display panel 100 is a top-emitting display panel, light transmittance of the cathode layer 10 and the compensation cathode 20 needs to be considered. Therefore, the dimension of the compensation cathode 20 in the first direction X may be 0.1d1-0.2d1. Specifically, the dimension of the cathode layer 10 in the first direction X may be 500 Å, and the corresponding dimension of the compensation cathode 20 in the first direction X may be 50 Å-100 Å.

The balance between resistance and light transmittance in the region corresponding to the blue sub-pixel 31 may be achieved by defining the dimensional relationship between the compensation cathode 20 and the cathode layer 10 in the first direction X. Additionally, the reduced size of the blue sub-pixel 31 region facilitates an increase in PPI of the display panel 100.

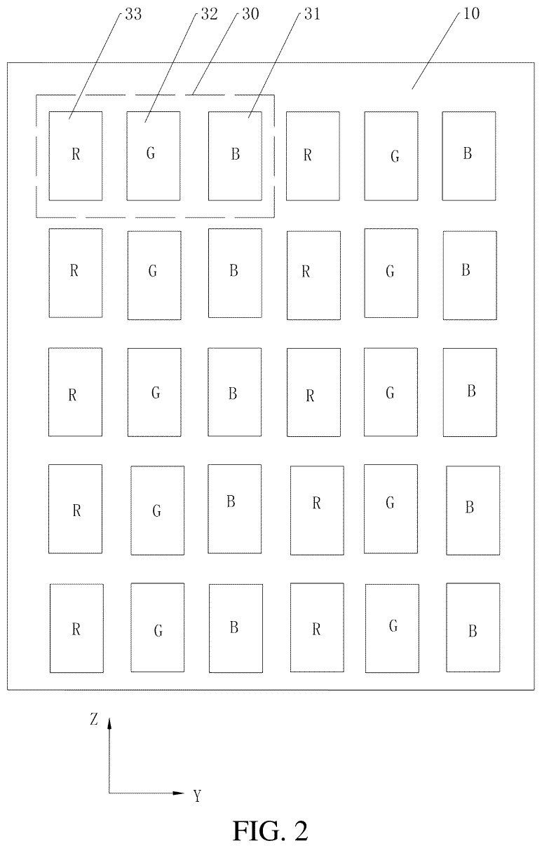

Reference is made to FIG. 1 and FIG. 2, in an embodiment, the display panel 100 further includes a red sub-pixel 33 and a green sub-pixel 32 stacked on the cathode layer 10. The red sub-pixel 33, the green sub-pixel 32, and the blue sub-pixel 31 are spaced apart from one another in a second direction Y and form one pixel 30, and the second direction Y intersects with the first direction X.

The red sub-pixel 33, the green sub-pixel 32, and the blue sub-pixel 31 in one pixel 30 are sequentially adjacent sub-pixels in the second direction Y.

The pixel 30 may be implemented as multiple pixels 30. The multiple pixels 30 are spaced apart from one another in the second direction Y and a third direction Z. Any two of the first direction X, the second direction Y, and the third direction Z intersect with each other.

In a single pixel 30, the dimensions and quantities of the red sub-pixel(s) 33, the green sub-pixel(s) 32, and the blue sub-pixel(s) 31 may be identical, partially identical, or completely different, which is not limited herein.

The material of the red sub-pixel 33 may be phosphorescent material, specifically including rubrene, PTPP, DCJTB, Tz-Gl, etc., which is not limited herein. The high light-emitting efficiency of the phosphorescent material provides excellent performance for the red sub-pixel 33, ensuring vividness and saturation of red light display.

The material of the green sub-pixel 32 may be phosphorescent material, specifically including Alaq3, TDETE, Coumarin, NpGl, etc., which is not limited herein. The efficient light-emitting characteristic of the phosphorescent material enables the green sub-pixel 32 to achieve stable green light display effect in the display panel 100.

Optionally, the arrangement of the red sub-pixel 33, the green sub-pixel 32, and the blue sub-pixel 31 in the pixel 30 may be RGB24 (24-bit true color), RGB32 (32-bit true color with alpha channel), RGB565, RGB555, etc., which is not limited herein. Specifically, for RGB24 arrangement, each pixel 30 is represented by 24 bits, which occupies 3 bytes, with 8 bits (0-255) allocated to each component of the red sub-pixel 33, the green sub-pixel 32, and the blue sub-pixel 31. The arrangement sequence may be that the blue sub-pixel 31, the green sub-pixel 32, and the red sub-pixel 33 arranged in sequence, or the red sub-pixel 33, the green sub-pixel 32, and the blue sub-pixel 31 arranged in sequence. For RGB32 arrangement, each pixel 30 is represented by 32 bits, which occupies 4 bytes, and the alpha channel is a channel corresponding to transparency, allocated with 8 bits. 8 bits (0-255) are allocated to each component of the red sub-pixel 33, the green sub-pixel 32, and the blue sub-pixel 31. The arrangement sequence may be that the blue sub-pixel 31, the green sub-pixel 32, the red sub-pixel 33, and the alpha channel arranged in sequence. For RGB565 arrangement, each pixel 30 is represented by 16 bits, which occupies 2 bytes, arranged as 5-bit red sub-pixel 33, 6-bit green sub-pixel 32, and 5-bit blue sub-pixel 31 in sequence.

The red sub-pixel 33, the green sub-pixel 32, and the blue sub-pixel 31 generate various colors through different brightness and combinations, thereby creating rich and colorful display images for the display panel 100. In the display panel 100 of the disclosure, the compensation cathode 20 is disposed on the region corresponding to the blue sub-pixel 31, and an additional PVEE signal may be input. By inputting signals to the compensation cathode 20 of the blue sub-pixel 31, a difference is created between the cathode signals of the red sub-pixel 33/the green sub-pixels 32 and the cathode signal of the blue sub-pixel 31. The voltage difference between PVDD (anode) and PVEE (cathode) may be increased, thereby enabling the blue sub-pixel 31 to obtain greater driving current. Since the driving current in the region corresponding to the blue sub-pixel 31 is increased, the area of the blue sub-pixel 31 within the pixel 30 may be reduced. Consequently, more pixels 30 may be accommodated per unit area of the display panel 100, thereby increasing the PPI of the display panel 100. Correspondingly, both image definition and resolution of the display panel 100 are improved.

In an embodiment, a dimension of the blue sub-pixel 31 in the second direction Y is not greater than dimensions of the red sub-pixel 33 and/or the green sub-pixel 32 in the second direction Y.

Optionally, the blue sub-pixel 31, the red sub-pixel 33, the green sub-pixel 32 are consistent in terms of dimension in the second direction Y. Further, the blue sub-pixel 31, the red sub-pixel 33, and the green sub-pixel 32 are consistent in terms of shape and dimension.

Since the compensation cathode 20 is disposed on the region corresponding to the blue sub-pixel 31, the driving voltage difference in the region corresponding to the blue sub-pixel 31 is greater than the driving voltage differences in the regions corresponding to the green sub-pixel 32 and red sub-pixel 33 when supplying current to the display panel 100. Therefore, the PVEE signal corresponding to the blue sub-pixel 31 becomes more stable, thereby ensuring the light-emitting current of the blue sub-pixel 31. Consequently, the area of the blue sub-pixel 31 may be reduced, allowing the area of the blue sub-pixel 31 to be the same as the area of the red sub-pixel 33 or green sub-pixel 32, or smaller than the area of the red sub-pixel 33 or the green sub-pixel 32. Compared to conventional display panels 100 with enlarged areas of the blue sub-pixel 31, the display panel 100 of the disclosure accommodates more pixels 30 within the same area, achieving increased PPI. That is, the display panel 100 exhibits high PPI, leading to improved image definition and resolution.

In one embodiment, the pixel 30 is implemented as multiple pixels 30. A distance between centers of two adjacent pixels 30 is d3, and d3 satisfies: 0.2 mm≤d3≤0.5 mm. Optionally, d3 may be 0.2 mm, 0.3 mm, 0.4 mm, 0.5 mm, etc., which is not limited herein.

When d3<0.2 mm, an excessively small distance between centers of the pixels 30 may cause visual fatigue of users. When d3>0.5 mm, an excessively large distance between centers of two adjacent pixels 30 may reduce the PPI of the display panel 100, resulting in poor image definition and display effect. When 0.2 mm≤d3≤0.5 mm, the appropriate distance between centers of two adjacent pixels 30 enables the display panel 100 to provide optimal visual experience without causing visual fatigue of users.

Reference is made to FIG. 1, in an embodiment, the display panel 100 further includes an anode layer 40. The anode layer 40 is disposed on one side of the blue sub-pixel 31 facing away from the cathode layer 10.

The material of the anode layer 40 is a transparent conductive material, such as carbon nanotube transparent conductive material, oxide transparent conductive material, metal transparent conductive material, which is not limited herein. Specifically, the oxide transparent conductive material may be zinc oxide, tin oxide, indium tin oxide (ITO), etc., and the metal transparent conductive material may be metal thin films such as silver, copper, gold, etc.

The anode layer 40 of the display panel 100 is configured to remove electrons and increase electron holes when current flows through a device.

Optionally, the anode layer 40 may be disposed corresponding to the cathode layer 10, or may be disposed corresponding to the blue sub-pixel 31, the green sub-pixel 32, and the red sub-pixel 33. That is, the anode layer 40 may be composed of a blue-pixel region anode 41, a green-pixel region anode 42, and a red-pixel region anode 43 correspondingly.

Optionally, the display panel 100 further includes a substrate, with the cathode layer 10 disposed on the substrate. The substrate may be an alkali glass substrate or an alkali-free glass substrate. Specifically, the alkali glass substrate may include soda-lime glass and neutral borosilicate glass, while the alkali-free glass may be alkali-free aluminosilicate glass, which is not limited herein.

Optionally, the display panel 100 further includes a hole transport layer disposed between the anode layer 40 and the pixel 30. The hole transport layer is configured to efficiently transport holes (positive charges) injected from the anode layer 40 to the pixel 30. During operation of the display panel 100, holes and electrons meet and recombine with each other within the pixel 30 to produce light emission.

Optionally, the display panel 100 further includes an electron transport layer disposed between the cathode layer 10 and the pixel 30. The electron transport layer is configured to transport electrons from the cathode layer 10 to the pixel 30. The electron transport layer may be made of organic materials with low electron affinity and high electron mobility, enabling efficient electron transport while preventing hole transport, thereby ensuring effective recombination of electrons and holes within the pixel 30.

In the display panel 100, the substrate, the anode layer 40, the hole transport layer, the pixel 30, the electron transport layer, and the cathode layer 10 collectively form the basic structure of the display panel 100, enabling the light-emitting effect of the display panel 100.

When current passes through the display panel 100, the anode layer 40 is configured to remove electrons and increases electron holes, which is conducive for conductivity and injection of holes to electrodes. The anode layer 40 is also configured to transport holes to the hole transport layer. The close arrangement between the anode layer 40 and the pixel 30 directly affects the display performance of the display panel 100.

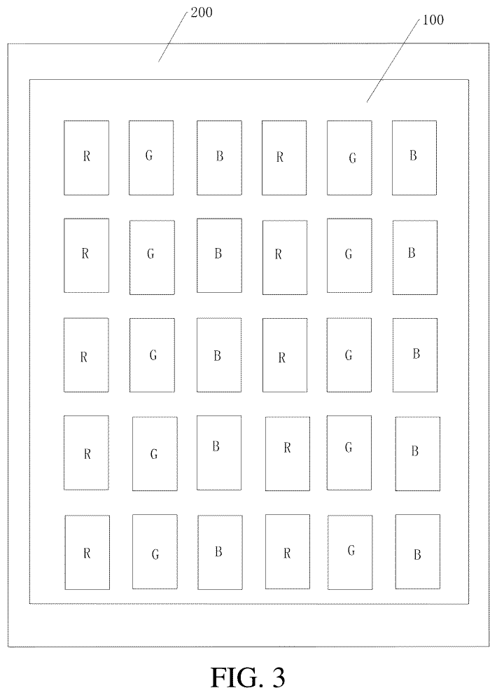

Reference is made to FIG. 3, the disclosure provides a display apparatus including a housing 200 and the display panel 100 of any of the aforementioned embodiments. The display panel 100 is accommodated in the housing 200.

The display apparatus may be a television, an electronic device, a monitor, etc., and the electronic device may be a cellphone, a computer, an intelligent wearable, etc., which is not limited herein.

Optionally, the display apparatus further includes a driving circuit, a control board, an interface, a power supply, and other components, etc.

The driving circuit is configured to provide correct voltages and signals to the display panel 100 for controlling the brightness and color of the pixel 30. The driving circuit may include a source driver and a gate driver, which are responsible for supplying signals to rows and columns of the display panel 100 respectively.

The control board is configured to receive signals from external devices (e.g., video signals) and convert these signals into signals interpretable by the driving circuit. The control board may also be configured to perform image processing to optimize the display effect of images.

The interface may be HDMI, DisplayPort, USB-C, etc., which is not limited herein. The interface enables the display apparatus to connect with external devices (e.g., computers, game consoles, media players).

The housing 200 is configured to provide physical protection and support for the display apparatus, while protecting internal components from dust, moisture, and other external factors.

The power supply is configured to provide required electrical power to the display apparatus, and the power supply may be a built-in alternating current (AC) adapter or a battery.

Other components may be a touch screen, a speaker, a camera, a sensor, etc.

In the display panel 100 of the display apparatus of the disclosure, the blue sub-pixel 31 is disposed on the cathode layer 10 and the compensation cathode 20 is correspondingly disposed on one side of the cathode layer 10 facing away from the blue sub-pixel 31, thereby increasing the total cathode thickness corresponding to the blue sub-pixel 31. When a PVEE signal is input, the electric field distribution weakens from the position of the compensation cathode corresponding to the blue sub-pixel 31 to other regions. Therefore, the electric field strength at the position of the cathode corresponding to the blue sub-pixel 31 is relatively high, and the PVEE signal corresponding to the blue sub-pixel 31 becomes more stable, thereby ensuring the light-emitting current of the blue sub-pixel. Therefore, the area of the blue sub-pixel 31 may be reduced, enabling the display panel 100 to accommodate more pixels 30 within the same area, achieving increased PPI. That is, the display panel 100 of the display apparatus exhibits high PPI, leading to improved image definition and resolution of the display apparatus.

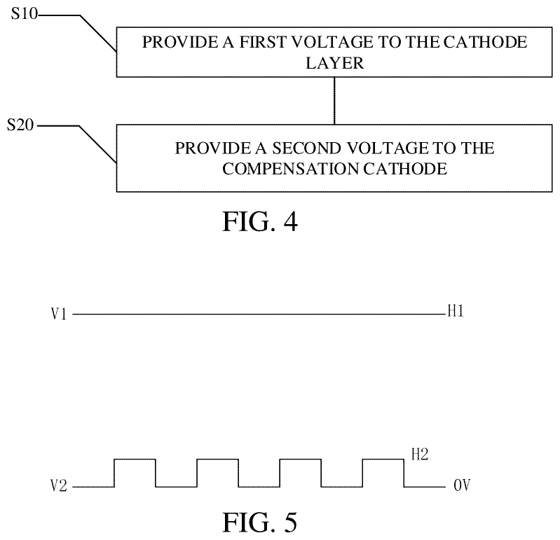

Reference is made to FIG. 4, the disclosure provides a driving method of the display panel 100, and the method is used for driving the display panel 100 of any aforementioned embodiments. The method includes the following.

At S10, a first voltage V1 is provided to the cathode layer 10.

At S20, a second voltage V2 is provided to the compensation cathode 20.

Optionally, an apparatus providing voltage to the cathode layer 10 and the compensation cathode 20 may be a power supply of the display apparatus. Specifically, voltage may be provided by a boosted built-in charge pump of the display apparatus.

Reference is made to FIG. 5, in an embodiment, the first voltage V1 is a stable voltage, and the second voltage V2 is a stable voltage or a pulse voltage.

Specifically, both the first voltage V1 and the second voltage V2 are stable voltages, and the second voltage V2 is not smaller than the first voltage V1. Alternatively, the first voltage V1 is a stable voltage, while the second voltage V2 is a pulse voltage. The first voltage V1 has a value of H1, the second voltage V2 corresponds to a voltage of H2 at high level, the second voltage V2 corresponds to a voltage of 0V at low level, and H1 and H2 satisfy: H1≤H2.

Optionally, types of pulse voltage may include rectangular pulse, square wave pulse, spike pulse, sawtooth pulse, stepped pulse, intermittent sinusoidal pulse, etc., which is not limited herein.

Optionally, the stable voltage may be 7V-10V. The light-emitting process of the display panel 100 includes stages such as carrier injection, carrier migration, carrier recombination, exciton migration, and electroluminescence under an external electric field.

Conventional display panels 100 typically employ a 7T1C circuit architecture to control light emission of devices of the display panels 100 by regulating current between PVDD (anode) and PVEE (cathode). In large-sized display panels 100, significant voltage drop occurs due to the large cathode area, leading to differences between cathode signals across the panels. This reduces currents flowing through each of the pixels 30, degrading the display effect of the display panels 100. In the driving method of the display panel 100 of the disclosure, the second voltage V2 is supplied to the compensation cathode 20, so as to enhance the electric field strength, thereby improving adjustability of the electric field distribution. Moreover, currents flowing through each of the pixels 30 tend to be consistent, thereby optimizing the display effect of the display panel 100.

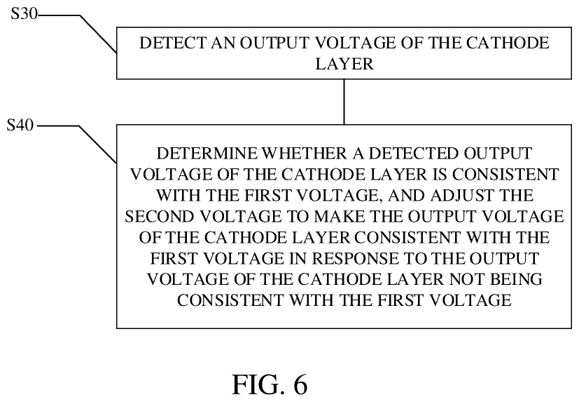

Reference is made to FIG. 6, in an embodiment, the method further includes the following.

At S30, an output voltage of the cathode layer 10 is detected.

At S40, whether a detected output voltage of the cathode layer 10 is consistent with the first voltage V1 is determined, and the second voltage V2 is adjusted to make the output voltage of the cathode layer 10 consistent with the first voltage V1 when the output voltage of the cathode layer 10 is not consistent with the first voltage V1.

Optionally, an apparatus for detecting the output voltage of the cathode layer 10 may include a reception module, a detection module, a calculation module, and a display module.

The reception module is configured to receive circuit detection requests regarding the cathode layer 10 to be tested, ensuring that the system is responsive to detection requests of users or automated procedure.

The detection module is configured to determine corresponding turn-on voltages of the blue sub-pixel 31, the green sub-pixel 32, and the red sub-pixel 33 in the pixel 30 from start-up state to turn-on state, and identify the driving voltage corresponding to the operational status of the pixel 30.

The calculation module is configured to determine abnormal pixels 30 among the pixels 30 in the display panel 100 according to corresponding turn-on voltages and driving voltages of the blue sub-pixel 31, the green sub-pixel 32, and the red sub-pixel 33 in each of the pixels 30. Through voltage and current data analysis, the calculation module is able to detect pixels 30 with current anomalies (e.g., overcurrent, undercurrent, or instability) and output the value of voltage required to be adjusted.

The display module may provide a first indication information (e.g., red warning light or error code) when the detected output voltage of the cathode layer 10 is inconsistent with the first voltage V1, and provide a second indication information (e.g., green indicator light indicating normal status) when the detected output voltage of the cathode layer 10 is consistent with the first voltage V1. The display module provides operators with straightforward visual feedback for rapid fault localization and resolution.

Optionally, detection of the output voltage of the cathode layer 10 and adjustment of the second voltage V2 may be synchronously performed in real-time. Alternatively, the output voltage of the cathode layer 10 may be detected during a first preset time period, and the second voltage V2 may be adjusted during a second preset time period, which is not limited herein.

It is to be noted that, the module described in the apparatus embodiment of the disclosure is presented in the form of functional units. The term “module” used herein should be understood as the broadest meaning as possible, and an object for implementing functions defined by each “module” may be, for example, an integrated circuit (ASIC), a single circuit, a processor (shared, dedicated, or chipset) and a memory for executing one or more software or firmware programs, a combinational logic circuit, and/or other suitable components that can achieve the above described functions.

In the driving method of the display panel 100 of the disclosure, operations S30 and S40 are added for adjusting the voltage of the compensation cathode 20, ensuring uniform light-emitting effect among the blue sub-pixel 31, the green sub-pixel 32, and the red sub-pixel 33 in each of the pixels 30 of the display panel 100 of the disclosure, thereby improving the display effect of the display panel 100.

In the description of the present disclosure, it should be noted that the terms “center”, “up”, “down”, “left”, “right”, “vertical”, “horizontal”, “inside”, “outside”, etc. indicate orientation or positional relationship based on the orientation or positional relationship shown in the drawings, are only for the convenience of describing the present disclosure and simplifying the description, rather than indicating or suggesting that the device or element must have a specific orientation and be constructed and operated in a specific orientation, thus cannot be understood as a limitation of the present disclosure.

The above embodiments may be preferred embodiments of the disclosure, and may not be used to limit the scope of the disclosure. Those of ordinary skill in the field may understand all or a part of the process that realizes the above embodiments, and equivalent changes made in accordance with the claims of the disclosure still belong to the scope of the disclosure.

What is claimed is:

1. A display panel, comprising:
a cathode layer;
a blue sub-pixel stacked on the cathode layer; and
a compensation cathode disposed on one side of the cathode layer facing away from the blue sub-pixel, wherein the compensation cathode and the blue sub-pixel are disposed opposite to each other in a first direction, and the first direction is a stacking direction of the blue sub-pixel and the cathode layer.

2. The display panel of claim 1, wherein an orthographic projection of the compensation cathode in the first direction is located within the blue sub-pixel.

3. The display panel of claim 1, wherein a dimension of the cathode layer in the first direction is d1, a dimension of the compensation cathode in the first direction is d2, and d1 and d2 satisfy: 0.1d1≤d2≤0.5d1.

4. The display panel of claim 1, further comprising a red sub-pixel and a green sub-pixel stacked on the cathode layer, wherein the red sub-pixel, the green sub-pixel, and the blue sub-pixel are spaced apart from one another in a second direction and form one pixel, and the second direction intersects with the first direction.

5. The display panel of claim 4, wherein a dimension of the blue sub-pixel in the second direction is not greater than dimensions of the red sub-pixel and the green sub-pixel in the second direction.

6. The display panel of claim 4, wherein the pixel is implemented as a plurality of pixels, a distance between centers of two adjacent pixels of the plurality of pixels is d3, and d3 satisfies: 0.2 mm≤d3≤0.5 mm.

7. The display panel of claim 1, further comprising an anode layer disposed on one side of the blue sub-pixel facing away from the cathode layer.

8. A display apparatus, comprising a housing and a display panel, wherein the display panel is accommodated in the housing, and the display panel comprises:
a cathode layer;
a blue sub-pixel stacked on the cathode layer; and
a compensation cathode disposed on one side of the cathode layer facing away from the blue sub-pixel, wherein the compensation cathode and the blue sub-pixel are disposed opposite to each other in a first direction, and the first direction is a stacking direction of the blue sub-pixel and the cathode layer.

9. The display apparatus of claim 8, wherein an orthographic projection of the compensation cathode in the first direction is located within the blue sub-pixel.

10. The display apparatus of claim 8, wherein a dimension of the cathode layer in the first direction is d1, a dimension of the compensation cathode in the first direction is d2, and d1 and d2 satisfy: 0.1d1≤d2≤0.5d1.

11. The display apparatus of claim 8, further comprising a red sub-pixel and a green sub-pixel stacked on the cathode layer, wherein the red sub-pixel, the green sub-pixel, and the blue sub-pixel are spaced apart from one another in a second direction and form one pixel, and the second direction intersects with the first direction.

12. The display apparatus of claim 11, wherein a dimension of the blue sub-pixel in the second direction is not greater than dimensions of the red sub-pixel and the green sub-pixel in the second direction.

13. The display apparatus of claim 11, wherein the pixel is implemented as a plurality of pixels, a distance between centers of two adjacent pixels of the plurality of pixels is d3, and d3 satisfies: 0.2 mm≤d3≤0.5 mm.

14. The display apparatus of claim 8, further comprising an anode layer disposed on one side of the blue sub-pixel facing away from the cathode layer.

15. A driving method of a display panel, being used for driving the display panel of claim 1, comprising:
providing a first voltage to the cathode layer; and
providing a second voltage to the compensation cathode.

16. The driving method of a display panel of claim 15, wherein the first voltage is a stable voltage, and the second voltage is a stable voltage or a pulse voltage.

17. The driving method of a display panel of claim 15, further comprising:
detecting an output voltage of the cathode layer; and
determining whether a detected output voltage of the cathode layer is consistent with the first voltage, and adjusting the second voltage to make the output voltage of the cathode layer consistent with the first voltage in response to the output voltage of the cathode layer not being consistent with the first voltage.
